(19) United States
(12) Patent Application Publication
(10) Pub. No.: US 2019/0387629 A1
(43) Pub. Date: Dec. 19, 2019

(54) DISPLAY PANEL AND DISPLAY

(71) Applicant: Wuhan China Star Optoelectronics Technology Co., Ltd., Wuhan, Hubei (CN)

(72) Inventors: Zhou ZHANG, Shenzhen, Guangdong (CN); Yucheng TSAI, Shenzhen, Guangdong (CN); Pan XU, Shenzhen, Guangdong (CN); Changwen MA, Shenzhen, Guangdong (CN)

(21) Appl. No.: 15/754,188

(22) PCT Filed: Dec. 19, 2017
(86) PCT No.: PCT/CN2017/117223

§ 371 Date: Feb. 21, 2018

(30) Foreign Application Priority Data
Aug. 25, 2017 (CN) 201710743326.7

(51) Int. Cl. H05K 1/18; H05K 1/02; G02F 1/13357; H05K 1/14; G02F 1/1345; H01R 12/79

(52) U.S. Cl. CPC H05K 1/189; H05K 1/0281; G02F 1/1336; H05K 2201/10128; G02F 1/13452; H01R 12/79; H05K 2201/10136; H05K 1/147

(57) ABSTRACT

A display panel is provided, which comprises a display module, a flexible connection board, a driver IC, and a passive component. The display module is electrically connected to the flexible connection board, the driver IC is disposed on the flexible connection board, and the passive component is disposed inside the driver IC. A display is also provided, which comprises a display panel and a circuit board. The display panel comprises a display module, a flexible connection board, a driver IC, and a passive component. The display module is electrically connected to the flexible connection board, the driver IC is disposed on the flexible connection board, and the passive component is disposed inside the driver IC or on the circuit board.

### RELATED APPLICATIONS

The present application is a National Phase of International Application Number PCT/CN2017/117223, filed Dec. 19, 2017, and claims the priority of China Application CN 201710743326.7 filed Aug. 25, 2017.

### FIELD OF THE DISCLOSURE

The present invention is related to display technology, and more particularly is related to a display panel and a display.

### BACKGROUND

Attending with the increasing demand of smart phones and tablets, people are asking for the smart phone and the tablets with a higher screen-to-body ratio, which implies a narrower frame. In order to implement the technology of ultimate narrow frame, chip on film (COF) technology has been widely researched and noticed, and become one of the important future development directions of display technology.

The conventional COF technology is to electrically connect the display module of the narrow frame design to the corresponding flexible connection board, and further electrically connect the display module to the flexible printed circuit (FPC) through the flexible connection board to compose the conventional display panel. The driver IC is disposed on the flexible connection board, the passive components are disposed on the FPC, and the FPC is connected to the system circuit board for driving the display panel. The existence of multiple components not only increases the product cost but also increases the connection costs between the components during the manufacturing process of the conventional display panel, such that the performance-price ratio of the product would be decreased.

### SUMMARY

It is an object of the present invention to provide a display panel and a display, which is capable to reduce the cost of the manufacturing process of the whole display panel so as to enhance the performance-price ratio of the product.

The display panel described in the present invention comprises a display module, a flexible connection board, a driver IC, and a passive component. The display module is electrically connected to the flexible connection board, the driver IC is disposed on the flexible connection board, and the passive component is disposed inside the driver IC.

In an embodiment, the flexible connection board is bendable to stack on a rear surface of the display module.

In an embodiment, the display module has a connector at one end thereof, the flexible connection board has a port at one end thereof with respective to the connector, and the flexible connection board is electrically connected to the display module through the port of the flexible connection board and the connector of the display module.

In an embodiment, the flexible connection board comprises an output side and an input side opposite to the output side, the port is located at the output side, the input side of the flexible connection board includes a front surface with golden fingers and a rear surface with a reinforce plate.

In an embodiment, the passive component comprises a resistor, a capacitor, an inductor, and a diode.

The display described in the present invention comprises the aforementioned display panel and a circuit board, wherein the passive component can be disposed on the circuit board. The circuit board is electrically connected to the flexible connection board through the golden fingers on the front surface of the input side of the flexible connection board.

In an embodiment, the display further comprises a backlight strip. The backlight strip has an upper end and a lower end opposite to the upper end;

wherein the upper end of the backlight strip is connected to the display module directly;

wherein the lower end of the backlight strip includes a front surface with golden fingers and a rear surface with a reinforce plate, and the backlight strip is electrically connected to the circuit board through the golden fingers on the front surface of the lower end thereof.

In accordance with the display panel and the display provided in the present invention, the original flexible printed circuit is removed, such that in addition to the cost of the flexible printed circuit, the cost for connecting the flexible connection board and the flexible printed circuit can be also saved, and thus the manufacturing cost can be further reduced to enhance performance-price ratio of the product.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts.

FIG. 1 is a planar schematic view of a display panel in accordance with the present invention.

FIG. 2 is a planar schematic view of a display in accordance with the present invention.

### DETAILED DESCRIPTION OF PREFERRED EMBODIMENTS

The present disclosure is described in detail below with references to the accompanying drawings and specific embodiments. Apparently, the embodiments in the description below are merely some embodiments of the present invention, the embodiments obtained by a person skilled in the art without creative efforts should be regarded as within the scope of the present invention.

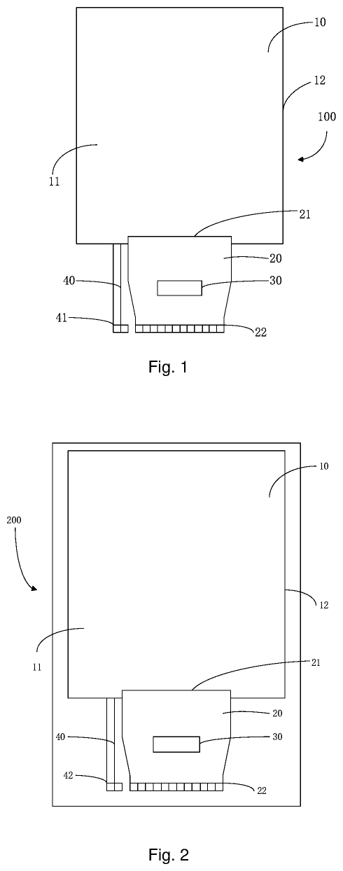

Please refer to FIG. 1, a display panel 100 is provided in the present invention, which includes a display module 10, a flexible connection board 20, a driver IC 30, and a passive component (not shown in FIG. 1). The flexible connection board 20 is connected to one side of the display module 10. The driver IC 30 is disposed on the flexible connection board 20. The passive component is disposed inside the driver IC 30.

In the present embodiment, the display module 10 includes a front surface 11 and a rear surface 12. The front surface 11 is the displaying surface of the display module 10, and the rear surface 12 is the non-displaying surface of the display module 10. The display module 10 includes, but is not limited to, a liquid crystal display (LCD) panel or an organic light emitting diode (OLED) display panel. The display module 10 has a connector at one side thereof.

The flexible connection board 20 includes an output side 21 and an input side 22 opposite to the output side. The flexible connection board 20 has a port located at the output side 21 thereof. The port at the output side 21 of the flexible connection board 20 is engaged with the connector of the display module 10. By using the anisotropic conductive film as a medium between the port at the output side 21 of the flexible connection board 20 and the connector of the display module 10, the thermal pressure process can be used to have the port at the output side 21 of the flexible connection board 20 and the connector of the display module 10 conducted, so as to have the flexible connection board 20 electrically connected to the display module 10. The input side 22 of the flexible connection board 20 includes a front surface and a rear surface thereof. The front surface of the input side 22 has golden fingers disposed thereon, and the rear surface of the input side 22 has a reinforce plate disposed thereon. The reinforce plate is utilized for supporting the golden fingers to enhance the structural strength of the golden fingers so as to facilitate the assembly of the product. The golden fingers on the front surface of the input side 22 of the flexible connection board 20 are used for electrical connecting a terminal. The connection ways include the method using the zero-insertion force connector or the method using the spring-pressure connector.

Furthermore, the flexible connection board 20 can be bended to stack on the rear surface 12 of the display module 10, such that the size of the lower side frame of the display panel 100 can be reduced to enhance the screen-to-body ratio of the smart phone or the tablet.

The driver IC 30 is fixed on the flexible connection board 20 by using the chip-on-film (COF) technology. The driver IC 30 includes, but is not limited to, the display driver IC and the touch control driver IC, which are utilized for providing the driving signals to the display module 10. Concretely speaking, the driver IC 30 may be fixed on the flexible connection board 20 by using conductive adhesive, wire-bonding, or welding. In the present embodiment, the driver IC 30 is fixed on the flexible connection board 20 by using the anisotropic conductive film. Because the flexible connection board 20 is electrically connected to the display module 10, the driving signals transmitted from the driver IC 30 can be used to control the operation of the display module 10.

The passive component is disposed inside the driver IC 30 or on the terminal. There are plated connection pins disposed inside the driver IC or no the terminal easy to be integrated with solder for connecting the passive component by welding. In the present embodiment, the passive component comprises a resistor, a capacitor, an inductor, and a diode. The resistor, the capacitor, the inductor, and/or the diode are disposed inside the driver IC 30 or on the terminal by welding through the plated connection pins with the solder such that the flexible printed circuit of the conventional display panel for placing the passive component can be skipped so as to reduce the overall cost of the whole display, and thus the performance-price ratio of the product can be enhanced.

In the embodiment of the present invention, the passive components originally disposed on the flexible printed circuit of the conventional display panel are disposed inside the driver IC or on the circuit board such that the flexible printed circuit of the conventional display panel can be skipped. In addition to the cost of the flexible printed circuit, the cost for connecting the flexible connection board and the flexible printed circuit can be also saved, such that the manufacturing cost can be further reduced to enhance performance-price ratio of the product.

Please refer to FIG. 2, a display 200 is also provided in the present invention, which includes a display panel 100 and a circuit board (not shown in FIG. 2). The circuit board can be used for locating the passive component. The circuit board is electrically connected to the flexible connection board 20 through the golden fingers on the front surface of the input side 22 of the flexible connection board 20. The connection ways include the method using the zero-insertion force connector or the method using the spring-pressure connector.

In the present embodiment, the display also includes a backlight strip 40. The backlight strip 40 has an upper end and a lower end 41 opposite to the upper end. The lower end includes a front surface and a rear surface. The front surface has golden fingers disposed thereon. The rear surface has a reinforce plate disposed thereon. The backlight strip 40 is electrically connected to the circuit board through the golden fingers of the lower end 41 thereof. The connection ways for connecting the lower end 41 of the backlight strip 40 and the circuit board include the method using the zero-insertion force connector or the method using the spring-pressure connector. Furthermore, the reinforce plate on the rear surface of the lower end 41 of the backlight strip 40 is capable to enhance the strength of the plug to facilitate the assembly of the product. Wherein, if the display module 10 is a LCD screen, the display would have the corresponding backlight strip; whereas, if the display module 10 is an OLED screen, the display would not have the corresponding backlight strip.

In the embodiments of the present invention, by placing the passive components originally located on the flexible printed circuit of the conventional display inside the driver IC or on the circuit board, the flexible printed circuit of the conventional display can be skipped. In addition, the flexible connection board is capable to be bended to the rear surface of the display module to implement the narrow frame design of the product. Thus, in addition to the cost of the flexible printed circuit, the cost for connecting the flexible connection board and the flexible printed circuit can be also saved, such that the manufacturing cost of the whole product can be reduced. In addition, the screen-to-body ratio can be enhanced. Thus, the overall performance-price ratio of the product can be enhanced.

The foregoing contents are detailed description of the disclosure in conjunction with specific preferred embodiments and concrete embodiments of the disclosure are not limited to the description. For the person skilled in the art of the disclosure, without departing from the concept of the disclosure, simple deductions or substitutions can be made and should be included in the protection scope of the application.

What is claimed is:

1. A display panel, comprising a display module, a flexible connection board, a driver IC and a passive component, wherein the display module is electrically connected to the flexible connection board, the driver IC is disposed on the flexible connection board, and the passive component is disposed inside the driver IC.

2. The display panel of claim 1, wherein the flexible connection board is bendable to stack on a rear surface of the display module.

3. The display panel of claim 1, wherein the display module has a connector at one end thereof, the flexible connection board has a port at one end thereof with respective to the connector, and the flexible connection board is electrically connected to the display module through the port of the flexible connection board and the connector of the display module.

4. The display panel of claim 3, wherein the flexible connection board comprises an output side and an input side opposite to the output side, the port is located at the output side, the input side of the flexible connection board includes a front surface with golden fingers and a rear surface with a reinforce plate.

5. The display panel of claim 1, wherein the passive component comprises a resistor, a capacitor, an inductor, and a diode.

6. A display, comprising a display panel and a circuit board, wherein the display panel comprises a display module, a flexible connection board, a driver IC and a passive component, wherein the display module is electrically connected to the flexible connection board, the driver IC is disposed on the flexible connection board, and the passive component is disposed inside the driver IC or on the circuit board.

7. The display of claim 6, wherein the flexible connection board is bendable to stacked on a rear surface of the display module.

8. The display of claim 6, wherein the display module has a connector at one end thereof, the flexible connection board has a port at one end thereof with respective to the connector, and the flexible connection board is electrically connected to the display module through the port of the flexible connection board and the connector of the display module.

9. The display of claim 8, wherein the flexible connection board comprises an output side and an input side opposite to the output side, the port is located at the output side, the input side of the flexible connection board includes a front surface with golden fingers and a rear surface with a reinforce plate, and the flexible connection board is electrically connected to the circuit board through the golden fingers on the front surface of the input side of the flexible connection board.

10. The display of claim 6, further comprising a backlight strip, which has an upper end and a lower end opposite to the upper end;
wherein the upper end of the backlight strip is connected to the display module directly;
wherein the lower end of the backlight strip includes a front surface with golden fingers and a rear surface with a reinforce plate, and the backlight strip is electrically connected to the circuit board through the golden fingers on the front surface of the lower end thereof.
